(19) United States
(12) Patent Application Publication
(10) Pub. No.: US 2005/0226085 A1
(43) Pub. Date: Oct. 13, 2005

(54) MULTI-FUNCTION DISPLAY DATA PROCESSING METHOD AND ASSOCIATED CONTROL DEVICE

(76) Inventor: Ming-Chieh Yeh, Hsin-Chu County (TW)

Correspondence Address: NORTH AMERICA INTELLECTUAL PROPERTY CORPORATION, P.O. BOX 506, MERRIFIELD, VA, 22116, US

(21) Appl. No.: 10/907,434

(22) Filed: Mar. 31, 2005

Related U.S. Application Data
(60) Provisional application No. 60/557,712, filed on Mar. 31, 2004.

(51) Int. Cl. G11C 8/00

(52) U.S. Cl. 365/230.05

(57) ABSTRACT

A method includes setting a plurality of predetermined stops in a line buffer of a port engine, writing a data set into the port engine, and checking the priority of a next service request after outputting data of the data set. A control device is coupled to a display device and memory for controlling the display device. The control device includes a plurality of input port engines, a plurality of output port engines, and a memory interface unit. Each input port engine includes a corresponding line buffer. The memory interface unit is coupled to the memory, the plurality of input port engines, and the plurality of output port engines, and transfer data between the output port engines, the memory and the output port engines. Data with the lowest priority is written inconsecutively into the memory based on a service length.

### CROSS REFERENCE TO RELATED APPLICATIONS

This is a non-provisional application of U.S. provisional application No. 60/557,712, which was filed on Mar. 31, 2004 and is included herein by reference.

### BACKGROUND OF INVENTION

1. Field of the Invention

The present invention is related to a data processing method and a control device of a multi-function display, and more particularly, to a data processing method and a control device of the multi-function display with adjustable line buffers.

2. Description of the Prior Art

With the rapid development of technology and the increased pace of daily life, multi-function products, such as multi-function printers, multi-function network equipment, and multi-function displays are becoming more and more popular in the consumer market. For example, the display of a personal computer that used to be a simple computer monitor has evolved into a multi-function display capable of receiving various visual signals including the television (TV) signal. Nowadays most people depend on TV for receiving information like weather, news, and movies. However, new technologies can allow a TV to no longer function solely as a passive display device that receives information broadcast by a TV station. The “Video on demand” (VOD) function allows consumers to request desired programs from the TV station. Also, the interactive TV allows consumers to shop, receive e-mails, answer video telephones, and play online games through the Internet.

FIG. 1 shows a diagram of a multi-function display capable of receiving three input signals: TV, computer, and video recorder. The multi-function display includes a memory device 10, a display device 20, and a control device 30. The memory device 10 stores data temporarily, the display device 20 displays output signals, and the control device 30 controls the input data, output data, and accesses the memory device 10.

Whether for a traditional cathode ray tube (CRT) display in which an image is produced by lighting up different areas of a phosphor coating by highly energized electron beams, or a liquid crystal display (LCD) in which an image is produced by applying different voltages to liquid crystal cells, scan line technology is used to process image signals. For a CRT, a scan line is a scanning route of an electron beam from the left end to the right end of the CRT screen. The brightness of the scan line is determined by the energy of the electron beam. For a LCD, scan lines are scan electrodes or data electrodes formed in a matrix. Different TV systems have different specifications about the scan lines or frame rates. Common display standards used today are the NTSC (National Television Standards Committee) standard, the PAL (phase alternating line) standard, and SECAM (Systeme Electronique Couleur Avec Memoire). With a left-to-right and up-to-down scanning direction of a screen, NTSC delivers 525 lines of resolution at 60 half-frames per second, PAL delivers 625 lines at 50 half-frames per second, and SECAM delivers 625 lines at 25 frames per second.

FIG. 2 is a diagram showing the display device 20 of the multi-function display in FIG. 1. Suppose the multi-function display in FIG. 1 is based on the NTSC standard and is currently receiving three input signals: computer screen, video screen, and on-screen display (OSD). Accordingly, some scan lines of the display device 20 have to handle more than one input signal at the same time. For example, the scan lines between the scan line 1 and the scan line 2 handle two input signals (computer screen and OSD), the scan lines between the scan line 3 and the scan line 4 handle two input signals (computer screen and video screen), and the scan lines between the scan line 2 and the scan line 3 handle three input signals (computer screen, video screen, and OSD).

FIG. 3 is a diagram showing the control device 30 of the multi-function display in FIG. 1. The control device 30 comprises a memory interface unit (MIU) 32, a plurality of input port engines 34, and a plurality of output port engines 36. The plurality of input port engines 34 handle input data. The plurality of output port engines 36 output data to the display device 20. The memory device 10 stores data temporarily. The MIU 32 is coupled to the memory device 10 for handling the data input and output between the plurality of input port engines 34, the plurality of output port engines 36, and the memory device 10.

FIG. 4 is a diagram of a port engine in the control device 20. The port engine includes two line buffers 42 and 44, each having a pointer 46 for recording the data position in the corresponding line buffer. The port engine preferably accesses data through a ping-pong operation. For example, the line buffer 42 writes data while the line buffer 44 reads data. After the line buffer 42 finishes reading data, it switches to a “write mode” and begins to write data. Meanwhile, the line buffer 44 also switches to a “read mode” and begins to read data. The switching between the “write mode” and the “read mode” of the line buffers 42 and 44 is the so-called ping-pong operation and the line buffers 42 and 44 have a ping-pong buffer structure.

Since the MIU 32 handles the data input and output between the plurality of input port engines 34, the plurality of output port engines 36 and the memory device 10, it is often required to process several service requests at the same time. If a second service request is issued before a first service request is completed, the second service request has to wait until the MIU 32 finishes processing the first service request. Similarly, a third service request will not be handled until the MIU 32 finishes the first and the second service requests.

FIG. 5 is a diagram of a prior art MIU 50 when handling service requests. Three different kinds of service requests are issued to the MIU 50 during scan lines m through m+2: “video read”, “OSD read”, and “video write”. A “video read” service request 51, an “OSD read” service request 52 and a “video write” service request 57 are issued during the scan line m; a “video read” service request 53 and an “OSD read” service request 54 are issued during the scan line m+1; and a “video read” service request 55 and an “OSD read” service request 56 are issued during the scan line m+2. Although the service request 57 is issued during scan line m, the service request 51 and the service request 52 issued earlier should be processed first, so the MIU 50 actually begins processing the service request 57 during scan line m+1. Similarly, the service request 53 and the service request 54 issued during scan line m+1 will not be handled until the MIU 50 finishes processing the service request 57 issued during the scan line m.

When the service request “OSD read” 56 is issued during the scan line m+2 while the MIU 50 is processing the service request “OSD read” 54 issued during the scan line m+1, it results in a conflict error that causes mistakes in data processing. The conflict error occurs when an MIU has not finished a service request issued by a port engine and the same port engine issues another service request.

When the service requests 51 and 52 are issued by different port engines, the service request 52 waits to be processed by the MIU 50. On the other hand, the “OSD read” service request 56 is issued while the MIU 50 is processing the “OSD read” service request 54. Since the “OSD read” service requests 54 and 56 are issued by the same port engine, the MIU 50 can not service the same port engine with different tasks at the same time. Therefore a conflict error occurs under this circumstance.

Usually two prior art approaches are used to solve the above-mentioned conflict error in the MIU 50. The first one is to increase the clock rate of the MIU 50. Increasing the clock rate of the MIU 50 also increases its speed of processing service requests and reduces the chances of conflict errors. However, increasing the clock rate also increases the power consumption of the multi-function display. Another method is to increase the bus width of the MIU 50, for example from 16 bits to 32 bits. Then the speed at which the MIU 50 processes service requests is increased. However, increasing the bus width of the MIU 50 increases the manufacturing cost.

### SUMMARY OF INVENTION

The present invention discloses a data processing method of a multi-function display. The method includes setting a plurality of predetermined stops in a line buffer of a port engine using a pointer, writing a data set comprising a plurality of pieces of data into the line buffer, and checking if there is a service request of higher priority to be executed after outputting data of the data set.

The present invention further discloses a control device of a multi-function display. The control device, coupled to a display device and memory for controlling the display device, includes a plurality of input port engines, a plurality of output port engines, and a memory interface unit. Each of the plurality of input port engines has a corresponding line buffer. The memory interface unit is coupled to the memory, the plurality of input port engines, and the plurality of output port engines, and is for transferring data between said input port engines, said memory, and said output port engines. In the present invention, an input port engine, of said input port engines, with low priority writes data stored in the corresponding line buffer into the memory inconsecutively in a plurality of times based on a service length.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of a prior art multi-function display receiving three input signals.

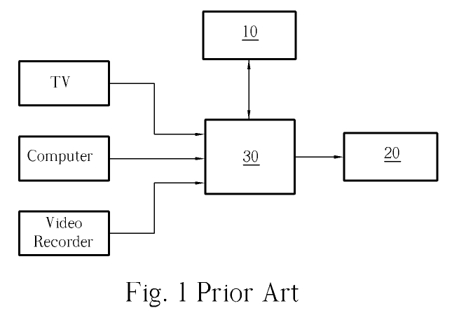

FIG. 2 is a diagram of a display device of the multi-function display in FIG. 1.

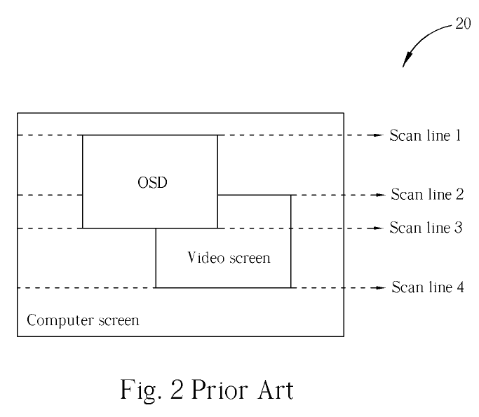

FIG. 3 is a diagram showing a control device of the multifunction display in FIG. 1.

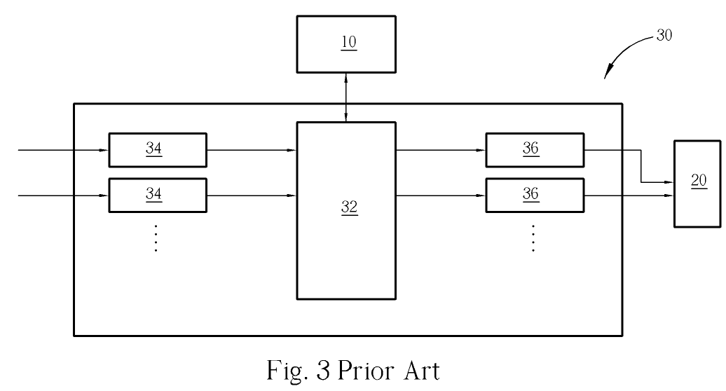

FIG. 4 is a diagram of a port engine in the control device in FIG. 3.

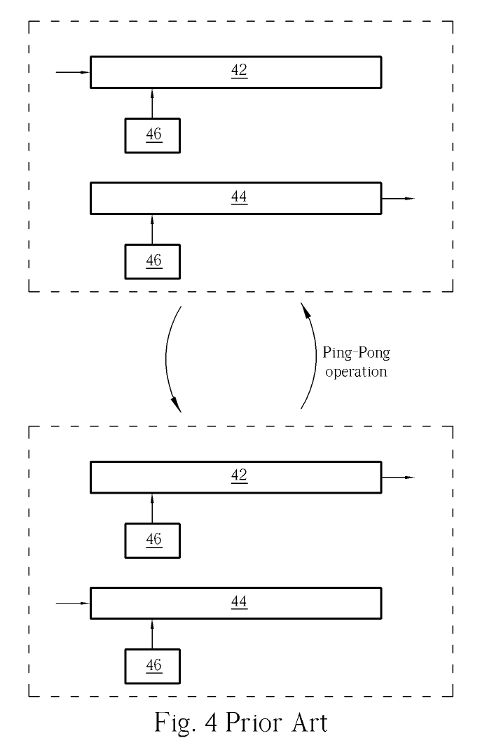

FIG. 5 is a diagram of a prior art memory interface unit when handling service requests.

FIG. 6 shows a line buffer structure with a pointer to perform multiple division access according to an embodiment of the present invention.

FIG. 7 is a diagram of a memory interface unit of the present invention when handling service requests.

FIG. 8 is a flowchart for handling service requests according to an embodiment of the present invention.

### DETAILED DESCRIPTION

In the present invention, the priority of each service request to be processed by a memory interface unit (MIU) in a multi-function display is firstly assigned. Based on a required service length, a pointer in a line buffer of a port engine is utilized to partition the service request with low priority to be associated with a data set comprising a plurality of pieces of data. Therefore the bus width of the MIU can be effectively utilized.

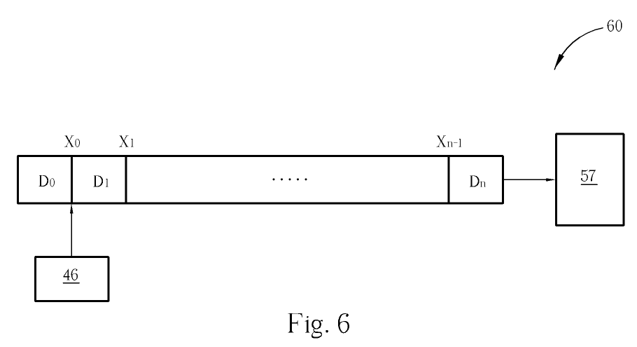

FIG. 6 shows a line buffer structure with a pointer to perform multiple division access according to an embodiment of the present invention. In this embodiment a “video write” service request is preferably chosen to be partitioned. In a port engine that handles the “video write” service request, a corresponding pointer 46 sets a plurality of predetermined stops X0, X1, . . . , Xn−1 in a corresponding line buffer 60. Therefore when the “video write” service request is being processed, data written into the line buffer 60 is read out and written into memory, preferably a dynamic random-access memory (DRAM), in the form of partitioned data D0, D1, . . . , Dn. In other words, when reading data from the line buffer 60 and writing data into the memory, the “video write” service request is handled as the partitioned data D0, D1, . . . , Dn which are stored between the plurality of predetermined stops X0, X1, . . . , Xn−1. Preferably, the line buffer 60 has a ping-pong buffer structure.

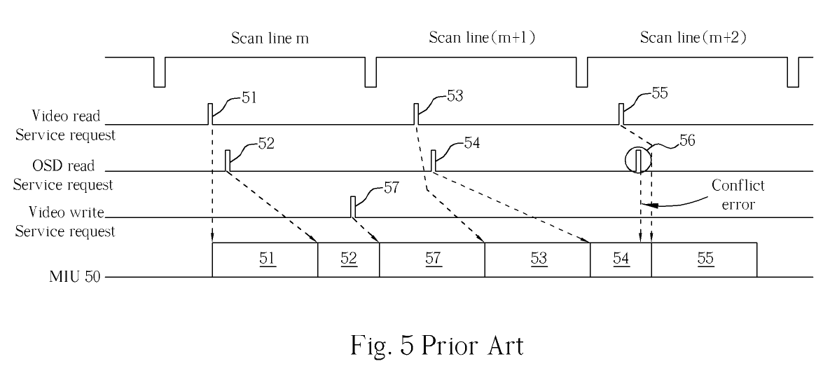

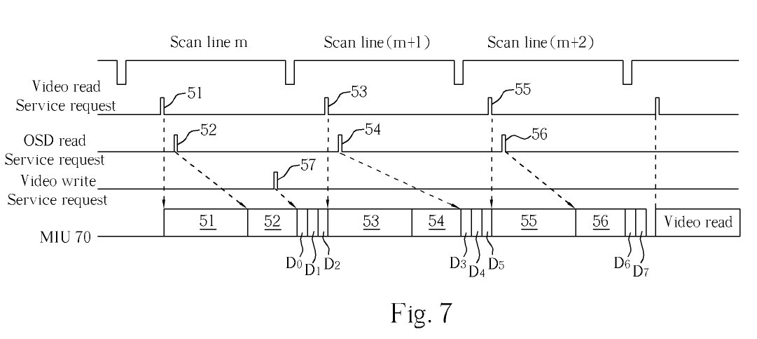

FIG. 7 is a diagram illustrating an MIU 70 of the present invention when handling service requests. Assume MIU 70 encounters the same service requests as the MIU 50 in FIG. 5. That is, a “video read” service request 51, an “OSD read” service request 52, and a “video write” service request 57 are issued during the scan line m; a “video read” service request 53 and an “OSD read” service request 54 are issued during the scan line m+1; and a “video read” service request 55 and an “OSD read” service request 56 are issued during the scan line m+2. According to the present invention, the “video write” service request 57 is set with low priority and chosen to be partitioned. In a port engine that handles the “video write” service request 57, the plurality of predetermined stops X0, X1, . . . , Xn−1 are set in the corresponding line buffer 60 by the pointer 46. When processing the “video write” service request 57, video data is written into the line buffer 60 and then the video data is read out and written into memory, preferably a DRAM, in the form of the data D0, D1, . . . , Dn. The number of data elements D0, D1, . . . , Dn is based on the required service length. The plurality of predetermined stops X0, X1, . . . , Xn−1 can be set based on the service length programmed in a corresponding register, the service length preferably being an integral multiple of a data bus width. In the present invention, the MIU 70 checks if there are other service requests of higher priority issued after each service length of the service request 57 is serviced.

Based on a predetermined service length, the MIU 70 in the present invention can choose to partition a service request with low priority. As shown in FIG. 7, the “video write” service request 57 is partitioned as D0-D7, which means setting seven predetermined stops X0-X6 in the line buffer 60 of the port engine that handles the “video write” service request 57. When the MIU 70 reads data from the line buffer 60 until the first predetermined stop X0, the MIU 70 checks if other service requests of higher priority are issued. When the “video write” service request 57 issued during the scan line m is processed till the first predetermined stop X0, which means D0 has been processed, the MIU 70 will firstly make sure no service requests of higher priority are issued before continuing to access the next data D1 from the predetermined stop X0. When the “video write” service request 57 is processed till the predetermined stop X2, which means D0-D2 have been processed, the MIU 70 receives the “video read” service request 53. Since the “video read” service request 53 and the subsequent “OSD read” service request 54 have higher priority, the MIU 70 executes the service request 53 and the service request 54 first while the pointer 46 stores the current location of the predetermined stop X2. After the MIU 70 completes the service request 53 and the service request 54 and confirms that no service request of higher priority is issued, the MIU 70 resumes processing the service request 57 from the predetermined stop X2. The MIU 70 repeats the same confirmation step at the following predetermined stops X3-X6. The conflict error in the prior art can thus be solved. In the present invention, an infrequent service request is preferably set as low priority and partitioned based on the required service length. Therefore when performing other service requests more frequently issued by the port engines, the conflict error can be avoided.

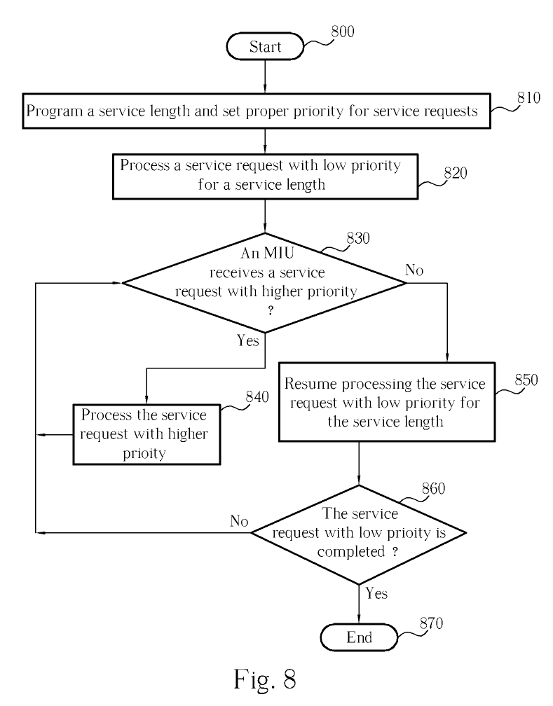

FIG. 8 is a flowchart showing the MIU 70 of the present invention when handling a service request, including the following steps:
Step 800: Start;
Step 810: Program a service length and set proper priority for service requests;
Step 820: Process a service request with low priority for a service length;
Step 830: Check if a MIU receives a service request with higher priority; if yes, execute step 840; if not, execute step 850;
Step 840: Process the service request with higher priority; return to step 830;
Step 850: Resume processing the service request of low priority for the service length;
Step 860: Check if the service request with low priority is completed; if not completed, execute step 830; if completed, execute step 870; and
Step 870: End.

In this embodiment, one service request is chosen to be partitioned, but the present invention is not limited to one service request. Several service requests can be partitioned. Based on their priorities, the MIU decides which service request should be processed first. Also, the plurality of predetermined stops are evenly distributed in the line buffer so that the data length defined by each adjacent predetermined stop is identical, providing the same service length for the partitioned service request. Persons skilled in the art should conceive setting the plurality of predetermined stops unevenly in the line buffer so that the data length defined by each adjacent predetermined stop is not identical, thus providing different service lengths for the partitioned service request.

The service requests are designated with priorities in the present invention. The service request with low priority is partitioned by setting a corresponding pointer of a corresponding line buffer in a corresponding port engine. Therefore the MIU of the present invention can use its data bus width more effectively and thus avoid conflict errors.

Those skilled in the art will readily observe that numerous modifications and alterations of the device and method may be made while retaining the teachings of the invention. Accordingly, the above disclosure should be construed as limited only by the metes and bounds of the appended claims.

1. A multi-function display data processing method, comprising:
setting a plurality of predetermined stops in a line buffer of a port engine using a pointer;
writing a data set comprising a plurality of pieces of data into the line buffer; and
checking if there is a service request of higher priority to be serviced after outputting data of the data set.

2. The method of claim 1 wherein the plurality of predetermined stops are evenly distributed in the line buffer.

3. The method of claim 1 wherein the plurality of predetermined stops are unevenly distributed in the line buffer.

4. The method of claim 1 wherein the port engine is an input port engine.

5. The method of claim 1 wherein the step of outputting data of the data set is reading the data of the data set from the line buffer and writing the data of the data set into a memory.

6. The method of claim 1 wherein the writing step writes the data set into the line buffer in response to a video write service request.

7. The method of claim 1 wherein the step of setting the plurality of predetermined stops in the line buffer of the port engine using the pointer is based on a predetermined service length stored in a register.

8. A multi-function display data processing method, comprising:
programming a service length;
servicing a service request with low priority for the service length;
checking whether a second service request with higher priority to be serviced exists; and
servicing the second service request if the second request exists.

9. The method of claim 8 wherein the service length is an integral multiple of a data bus width.

10. A multi-function display control device coupled to a display device and a memory for controlling the display device, the control device comprising:
a plurality of input port engines, each comprising a corresponding line buffer;
a plurality of output port engines; and
a memory interface unit (MIU) coupled to the memory, the plurality of input port engines, and the plurality of output port engines, for transferring data between said input port engines, said memory, and said output port engines;
wherein an input port engine, of said input port engines, with low priority writes data stored in the corresponding line buffer into the memory inconsecutively in a plurality of times based on a service length.

11. The control device of claim 10 wherein the input port engine with low priority writes data stored in the corresponding line buffer into the memory inconsecutively based on the service length in response to a service request with low priority.

12. The control device of claim 11 wherein the service request of low priority is a video write service request.

13. The control device of claim 11 wherein the service length is an integral multiple of a data bus width of the memory.

14. The control device of claim 11 wherein the memory is dynamic random-access memory.

15. The control device of claim 11 wherein the input port engine with low priority records a service location in the corresponding line buffer using a pointer.

16. The control device of claim 11 wherein when a service request with higher priority is issued, the MIU pauses the service request with low priority currently being processed and begins processing the service request with higher priority.

17. The control device of claim 16 wherein the service request with higher priority is a video read service request.

18. The control device of claim 16 wherein the service request with higher priority is an on-screen display (OSD) read service request.

19. The control device of claim 16 wherein the service request of low priority is issued less frequently than the service request with higher priority.

20. The control device of claim 16 wherein each line buffer is a ping-pong buffer.
